(19) United States
(12) Patent Application Publication
(10) Pub. No.: US 2025/0017092 A1
(43) Pub. Date: Jan. 9, 2025

(54) METHOD OF MANUFACTURING DISPLAY DEVICE AND VAPOR DEPOSITION MASK

(71) Applicant: Japan Display Inc., Tokyo (JP)

(72) Inventors: Naoya IWAHASHI, Tokyo (JP); Sho YANAGISAWA, Tokyo (JP); Mitsugu TAMEKAWA, Tokyo (JP)

(73) Assignee: Japan Display Inc., Tokyo (JP)

(21) Appl. No.: 18/763,281

(22) Filed: Jul. 3, 2024

(30) Foreign Application Priority Data
Jul. 7, 2023 (JP) 2023-112448

(51) Int. Cl. H10K 71/16; C23C 14/04; C23C 14/12; C23C 14/24

(52) U.S. Cl. CPC H10K 71/166; C23C 14/042; C23C 14/12; C23C 14/24

(57) ABSTRACT

According to one embodiment, a method of manufacturing a display device includes depositing an organic EL material from an evaporation source onto the substrate via the vapor deposition mask by heating the evaporation source, thereby forming an organic EL layer, wherein the vapor deposition mask comprises a plurality of thin-film regions and a retaining frame, each of the plurality of thin-film regions includes a plurality of mask regions and connection regions, each of the plurality of thin-film regions has a propeller shape, each of the plurality of mask regions has a circular shape, and each of the plurality of mask regions comprises a plurality of aperture regions.

### CROSS-REFERENCE TO RELATED APPLICATIONS

This application is based upon and claims the benefit of priority from Japanese Patent Application No. 2023-112448, filed Jul. 7, 2023, the entire contents of which are incorporated herein by reference.

### FIELD

Embodiments described herein relate generally to a display device.

### BACKGROUND

In the process of manufacturing organic EL display devices, the vacuum evaporation method is used to form a layer (organic EL layer) made of an organic EL material. In the vacuum evaporation method, a vapor deposition mask is brought into close proximity to the substrate to be processed, and the organic EL material is deposited onto the substrate via the vapor deposition mask. The vapor deposition mask has a plurality of apertures. Since the organic EL material passes through these apertures and reaches the substrate to be processed, it is possible to form an organic EL layer selectively at locations corresponding to the plurality of apertures.

### BRIEF DESCRIPTION OF THE DRAWINGS

FIG. 1 is an overall perspective view showing a display device of an embodiment.

FIG. 2 is a partial plan view schematically showing an example of a configuration of the display device.

FIG. 3 is a cross-sectional view showing the display device taken along line A1-A2 in FIG. 2.

FIG. 4 is a cross-sectional view showing a processing step in a method of manufacturing the display device.

FIG. 5 is a cross-sectional view showing another processing step in the method of manufacturing the display device.

FIG. 6 is a cross-sectional view showing still another processing step in the method of manufacturing the display device.

FIG. 7 is a plan view showing a configuration of a vapor deposition mask.

FIG. 8 is a plan view schematically showing an example of a configuration of the display device.

FIG. 9 is a cross-sectional view showing the display device taken along line B1-B2 in FIG. 2.

FIG. 10 is a cross-sectional view showing the vapor deposition mask and a mother board, taken along line C1-C2 shown in FIG. 7.

FIG. 11 is a cross-sectional view showing the vapor deposition mask and the mother board after completion of a deposition step.

FIG. 12 is a plan view showing a configuration of the vapor deposition mask.

FIG. 13 is a plan view showing a configuration of the vapor deposition mask.

FIG. 14 is a cross-sectional view showing the vapor deposition mask and the mother board, taken along line D1-D2 shown in FIG. 13.

FIG. 15 is a cross-sectional view showing a processing step in the method of manufacturing the display device, which employs the vapor deposition mask shown in FIG. 13.

FIG. 16 is a cross-sectional view showing another processing step in the method of manufacturing the display device, which employs the vapor deposition mask shown in FIG. 13.

FIG. 17 is a cross-sectional view showing still another processing step in the method of manufacturing the display device, which employs the vapor deposition mask shown in FIG. 13.

FIG. 18 is a cross-sectional view showing still another processing step in the method of manufacturing the display device, which employs the vapor deposition mask shown in FIG. 13.

FIG. 19 is a cross-sectional view showing still another processing step in the method of manufacturing the display device, which employs the vapor deposition mask shown in FIG. 13.

FIG. 20 is a cross-sectional view showing still another processing step in the method of manufacturing the display device, which employs the vapor deposition mask shown in FIG. 13.

FIG. 21 is a cross-sectional view showing still another processing step in the method of manufacturing the display device, which employs the vapor deposition mask shown in FIG. 13.

### DETAILED DESCRIPTION

In general, according to one embodiment, a method of manufacturing a display device, comprises
disposing a substrate including a plurality of panel regions on a board carrier;
disposing a vapor deposition mask to oppose the substrate;
disposing a magnet to oppose the vapor deposition mask while interposing the substrate therebetween;
bringing the vapor deposition mask into close proximity to the substrate by a magnetic force of the magnet; and
depositing an organic EL material from an evaporation source onto the substrate via the vapor deposition mask by heating the evaporation source, thereby forming an organic EL layer, wherein
the vapor deposition mask comprises a plurality of thin-film regions and a retaining frame,
each of the plurality of thin-film regions includes a plurality of mask regions and connection regions,
each of the plurality of thin-film regions has a propeller shape,
each of the plurality of mask regions has a circular shape, and
each of the plurality of mask regions comprises a plurality of aperture regions.

According to another embodiment, a vapor deposition mask comprises
a plurality of thin-film regions and a retaining frame, wherein
each of the plurality of thin-film regions includes a plurality of mask regions and connection regions,
each of the plurality of thin-film regions has a propeller shape,
each of the plurality of mask regions has a circular shape,
each of the plurality of mask regions comprises a plurality of aperture regions,
four of the mask regions are provided in each one the thin-film regions,
each of the thin-film regions comprises four first regions which are ellipse-shaped and surround the four mask regions, a second region surrounded by the four first regions, and a third region provided between each adjacent pair of the first regions.

An object of this embodiment is to provide a display device with improved production yield.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### Embodiment

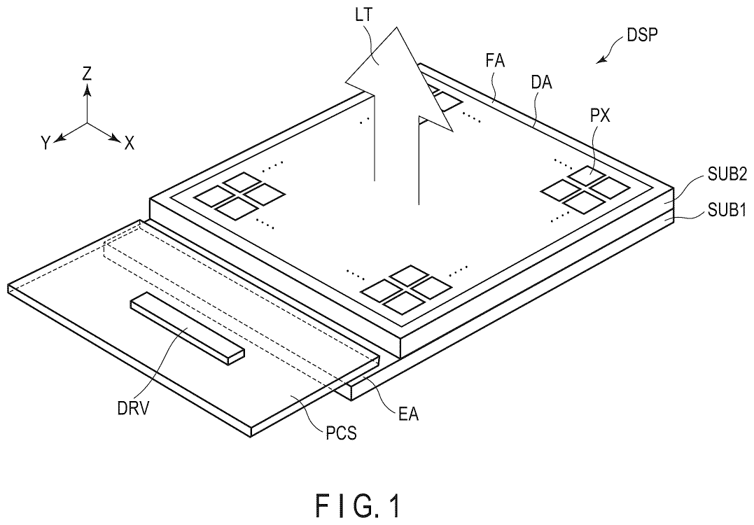

FIG. 1 is an overall perspective view showing a display device of an embodiment. A display device DSP comprises a display area DA and a peripheral area FA provided around the display area DA on a substrate SUB1. The display device DSP includes a plurality of pixels PX arranged in the display area DA. In the display device DSP, light LT from the rear surface is transmitted through to the surface thereof and vice versa.

An area EA, which is an end portion of the substrate SUB1 is located on an outer side of a substrate SUB2. In the area EA, a wiring board PCS is provided. The wiring board PCS is provided with a drive element DRV that outputs video signals and drive signals. Signals from the drive element DRV are input to the pixels PX in the display area DA via the wiring board PCS. Based on the video signals and various types of control signals, the pixels PX emit light.

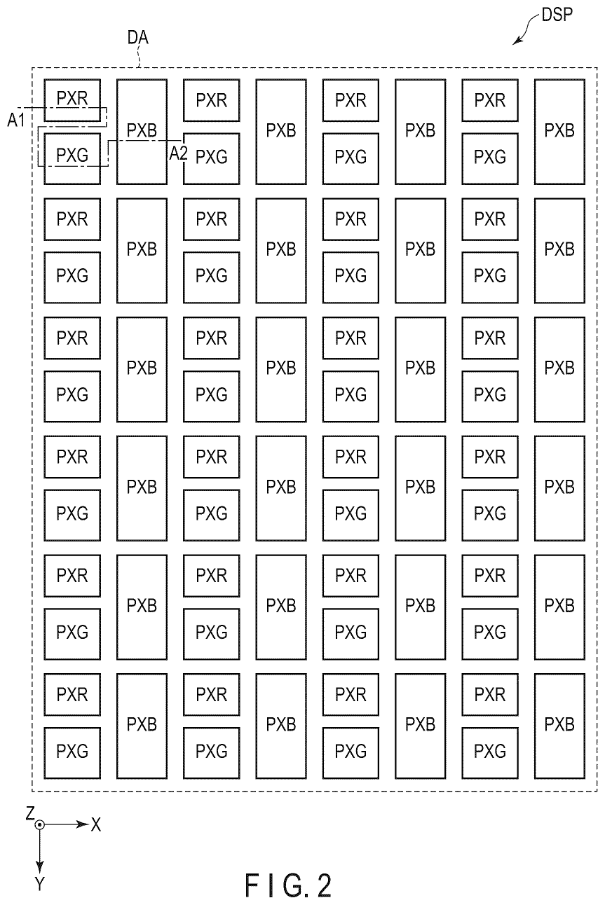

FIG. 2 is a partial plan view schematically showing an example of a configuration of the display device. The plurality of pixels PX include pixels PXR which emit red color, pixels PXG which emit green color, and pixels PXB which emit blue color. The pixels PXR, pixels PXG, and pixels PXB may as well be referred to as the first pixels, second pixels, and third pixels, respectively.

The pixels PXR are each disposed to be adjacent to a respective pixel PXB along the first direction X. The pixels PXR is disposed to be adjacent to a respective pixel PXG along the second direction Y.

The pixels PXG are each disposed adjacent to a respective pixel PXB along the first direction X. The pixels PXG are each disposed adjacent to a respective pixel PXR along the second direction Y.

The pixels PXB are each disposed adjacent to a respective pixel PXR and a respective pixel PXG along the first direction X. The pixels PXB are each disposed adjacent to another pixel PXB along the second direction Y.

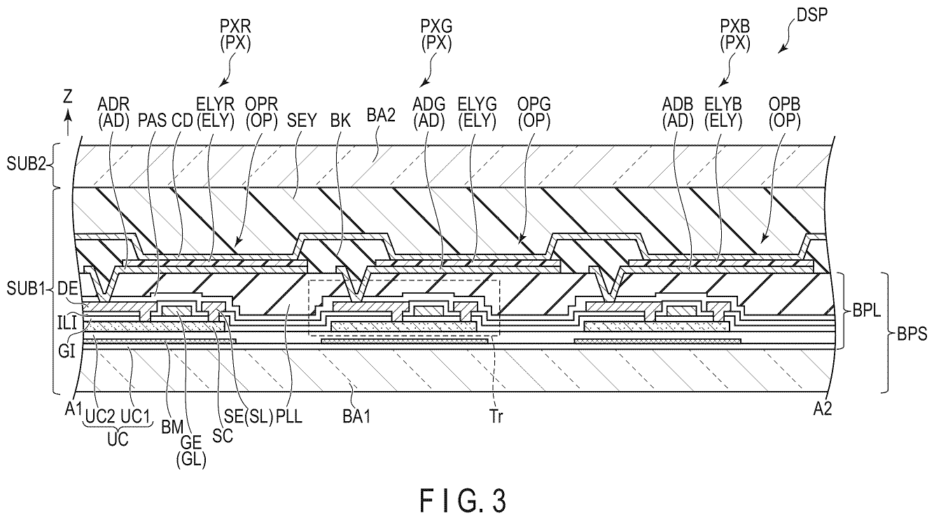

FIG. 3 is a cross-sectional view showing the display device taken along line A1-A2 in FIG. 2.

The base BAL is formed, for example, glass or a resin material. Usable examples of the resin material are acrylic, polyimide, polyethylene terephthalate, polyethylene naphthalate and the like, and may be formed from a single layer or a stacked body of multiple layers of any of these materials.

On the base BAL, an insulating layer UC1 is provided. The insulating layer UC1 is formed, for example, from a single layer of or a stacked body of one or both of a silicon oxide film and a silicon nitride film.

On the insulating layer UC1, a light-shielding layer BM may be provided to overlap a transistor Tr. The light-shielding layer BM suppresses changes in transistor characteristics, which may be caused by light penetration or the like, from the rear surface of the channel of the transistor Tr. When the light-shielding layer BM is formed from a conductive layer, it is also possible to impart a back-gate effect to the transistor Tr by applying a predetermined potential.

The insulating layer UC2 is provided to cover the insulating layer UC1 and the light-shielding layer BM. A material similar to that of the insulating layer UC1 can be used for the insulating layer UC2 as well. The insulating layer UC2 may be formed of a material different from that of the insulating layer UC1. For example, silicon oxide can be used for the insulating layer UC1, whereas silicon nitride for insulating layer UC2. The insulating layers UC1 and UC2 are collectively referred to an insulating layer UC.

The transistor Tr is provided on the insulating layer UC. The transistor Tr includes a semiconductor layer SC, an insulating layer GI, a gate electrode GE (scanning line), an insulating layer ILI, a source electrode SE (signal line) and a drain electrode DE.

Amorphous silicon, polysilicon, or oxide semiconductor is used as the semiconductor layer SC.

As the insulating layer GI, for example, silicon oxide or silicon nitride is provided to form a single layer or a stacked body of layers of these.

For example, a molybdenum-tungsten alloy (MoW) is used as the gate electrode GE. The gate electrode GE may as well be formed to be integrated with the scanning line GL as on body.

The insulating layer ILI is provided to cover the semiconductor layer SC and the gate electrode GE. The insulating layer ILI is formed, for example, from a single layer of a silicon oxide layer or silicon nitride layer or a stacked body of layers of these.

On the insulating layer ILI, the source electrode SE and the drain electrode DE are provided. The source electrode SE and the drain electrode DE are connected to the source region and drain region of the semiconductor layer SC, respectively, via contact holes formed in the insulating layer ILI and the insulating layer GI, respectively. The source electrode SE may as well be formed to be integrated with the signal line as one body.

An insulating layer PAS is provided to cover the source electrode SE, the drain electrode DE, and the insulating layer ILI. An insulating layer PLL is provided to cover the insulating layer PAS.

The insulating layer PAS is formed from an inorganic insulating material. As the inorganic insulating material, for example, a single layer of silicon oxide or silicon nitride or a stacked body layers of these can be used. The insulating layer PLL is formed from an organic insulating material. Examples of the organic insulating material include, for example, photosensitive acrylic, polyimide, and other organic materials. With the insulating layer PLL thus provided, steps caused by the transistor Tr can be planarized.

An anode AD is provided on the insulating layer PLL. The anode AD is connected to the drain electrode DE via contact holes formed in the insulating layer PAS and PLL. The anode provided in each pixel PXR is referred to as an anode ADR, the anode provided in each pixel PXB is referred to as an anode ADB, and the anode provided in each pixel PXG is referred to as an anode ADG. When there is no need to distinguish between the anode ADR, anode ADG, and anode ADB, they are simply referred to as anodes AD.

The anodes AD, for example, should be formed from a stacked body of a reflective electrode and a transparent electrode. The reflective electrode is formed from a conductive material having high reflectivity, that is, for example, silver (Ag) or a molybdenum-tungsten alloy (MoW). The transparent electrode is formed using indium tin oxide (ITO) and indium zinc oxide (IZO), for example.

In this embodiment, the configuration from the base BAL to the insulating layer PLL is referred to as a backplane BPS. Further, the configuration from the insulating layer UC1 to the insulating layer PLL is referred to as a backplane layer BPL.

A bank BK (which may as well be referred to as a projecting portion or rib) is provided between each adjacent pair of anodes AD. As the material of the bank BK, an organic material similar to the material of the insulating layer PLL is used. The bank BK is opened to expose a portion of each anode AD.

Here, the aperture formed in each pixel PXR is referred to as an apertures OPR, the aperture formed in each pixel PXB is referred to as an aperture OPB, and the aperture formed in each pixel PXG is referred to as an aperture OPG. When there is no need to distinguish between the aperture OPR, aperture OPB, and aperture OPG, they are simply referred to as apertures OP.

Note that it is preferable that an end portion of each aperture OP should be gently tapered in cross-sectional view. When the end portion of the aperture OP has a steep shape, coverage error may occur in the organic EL layer ELY, which is formed in a later step.

The organic EL layer ELY is provided between each adjacent portions of the bank BK so as to overlap the respective anode AD. As will be described in detail later, the organic EL layer ELY includes a hole injection layer HIL, a hole transport layer HTL, an emission layer EML, an electron transport layer ETL, and an electron injection layer EIL. The organic EL layer ELY may further include an electron blocking layer, a hole blocking layer, if necessary.

Here, the organic EL layer provided in each pixel PXR is referred to as an organic EL layer ELYR, the organic EL layer provided in each pixel PXB is referred to as an organic EL layer ELYB, and the organic EL layer provided in each pixel PXG is referred to as an organic EL layer ELYG. When there is no need to distinguish between the organic EL layer ELYR, organic EL layer ELYG, and organic EL layer ELYB, they are simply referred to organic EL layers ELY.

A cathode CD is provided on the organic EL layer ELY. The cathode CD is formed, for example, from a magnesium-silver alloy (MgAg) film, a single-layered film of silver (Ag), or a staked layered film of silver (Ag) and a transparent conductive material. For the transparent conductive material, indium tin oxide (ITO) and indium zinc oxide (IZO), for example, can be used.

An insulating layer SEY is provided to cover the cathode CD. The insulating layer SEY has the function of preventing moisture from entering the organic EL layer ELY from the outside. As the insulating layer SEY, a material with high gas barrier property is preferable. As the insulating layer SEY, for example, an insulating layer formed by interposing an organic insulating layer between two inorganic insulating layers containing nitrogen, can be used. Examples of the material for the organic insulating layer include acrylic resin, epoxy resin, polyimide resin and the like. Examples of the material of the inorganic insulating layer containing nitrogen include silicon nitride, aluminum nitride and the like.

On the insulating layer SEY, a base BA2 is provided. The base BA2 is formed of a material similar to that of the base BAL. Between the base BA2 and the insulating layer SEY, an inorganic insulating layer or organic insulating layer having translucency may as well be provided. The organic insulating layer may have the function of adhering the insulating layer SEY and the base BA2 to each other.

The light emission generated in the organic EL layer ELY is extracted upward via the cathode CD. In other words, the display device DSP of this embodiment has a top emission structure.

The configuration from the base BAL to the insulating layer SEY corresponds to the substrate SUB1 shown in FIG. 1. The base BA2 corresponds to the substrate SUB2 shown in FIG. 1.

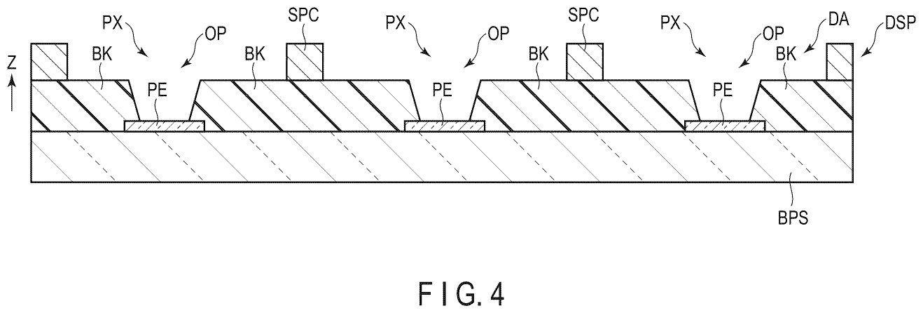

FIGS. 4 to 6 are cross-sectional views illustrating a method of manufacturing the display device. Note that FIGS. 4 to 6 mainly illustrate the method of manufacturing the pixel electrode PE, organic EL layer ELY, and common electrode CE.

A backplane layer BPL is provided on the base BA1 to form the backplane BPS. After forming the backplane BPS, the pixel electrode PE is formed. Although not shown in the figure, the pixel electrode PE is connected to the drain electrode DE of the transistor Tr. The bank BK is formed between each adjacent pair of pixel electrodes PE (see FIG. 4). Between each adjacent portions of the bank BK, an aperture OP is formed. The pixel electrode PE is exposed in the respective aperture OP. On the bank BK, a spacer SPC is provided.

In this embodiment, the anode AD is formed as described above, as the pixel electrode PE. The pixel electrode PE is not limited to an anode AD, but may as well be a cathode CD. In other words, the pixel electrode PE is one of an anode AD and a cathode CD.

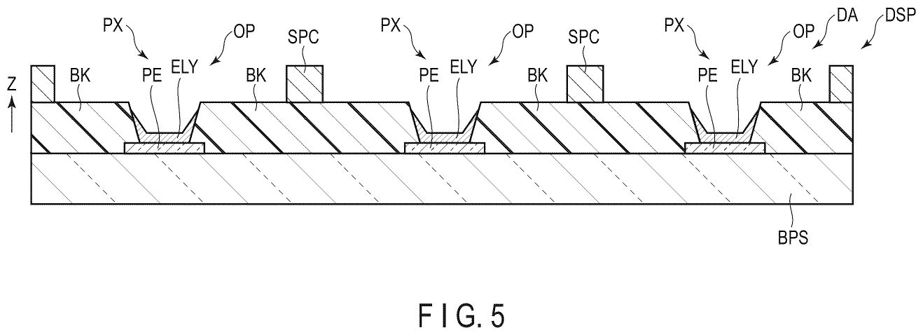

An organic EL layer ELY is formed on the pixel electrode PE and between each adjacent portions of the bank BK (see FIG. 5). The organic EL layer ELY includes a hole injection layer HIL, a hole transport layer HTL, an emission layer EML, an electron transport layer ETL, and an electron injection layer EIL, as described above.

When the pixel electrode PE is the anode AD, the hole injection layer HIL, the hole transport layer HTL, the emission layer EML, the electron transport layer ETL, and the electron injection layer EIL are stacked in this order as the organic EL layer ELY. On the other hand, when the pixel electrode PE is a cathode CD, the electron injection layer EIL, the electron transport layer ETL, the emission layer EML, the hole transport layer HTL, and the hole injection layer HIL are stacked in this order.

The organic EL layer ELY is formed by the vapor deposition method using a vapor deposition mask. In the vapor deposition method, a stacked body of the backplane BPS, the pixel electrode PE, and the bank BK is disposed to oppose the vapor deposition source containing the organic EL material. The vapor deposition mask is placed between the stacked body and the deposition source. As will be described in detail later, the vapor deposition mask has apertures in the regions corresponding to the apertures OP. The organic EL material contained in the deposition source is heated and deposited inside the apertures OPs via the aperture regions of the vapor deposition mask. The organic EL material deposited in each of the apertures OP forms the organic EL layer ELY.

FIG. 5 shows the method of forming the organic EL layer ELY in one display device DSP. However, for the purpose of yield improvement, the organic EL layer is formed on a mother board MSB containing a plurality of backplanes BPS.

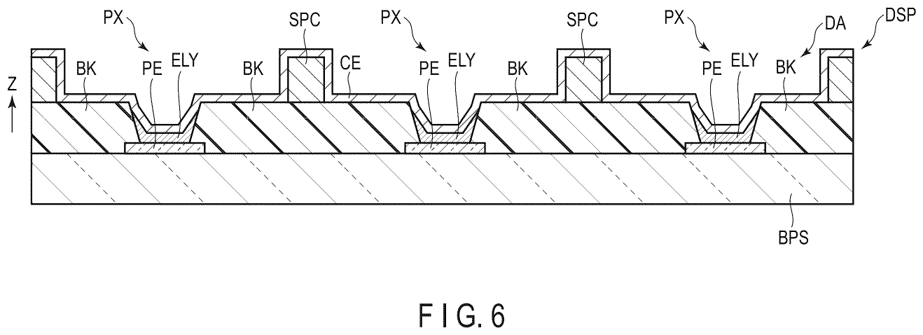

The common electrode CE is formed on the organic EL layer ELY, the bank BK, and the spacer SPC (see FIG. 6). In this embodiment, the cathode CD is formed as described above, as the common electrode CE. The pixel electrode PE is not limited to a cathode CD, but may as well be an anode AD. In other words, the common electrode CE is the other one of an anode AD and a cathode CD.

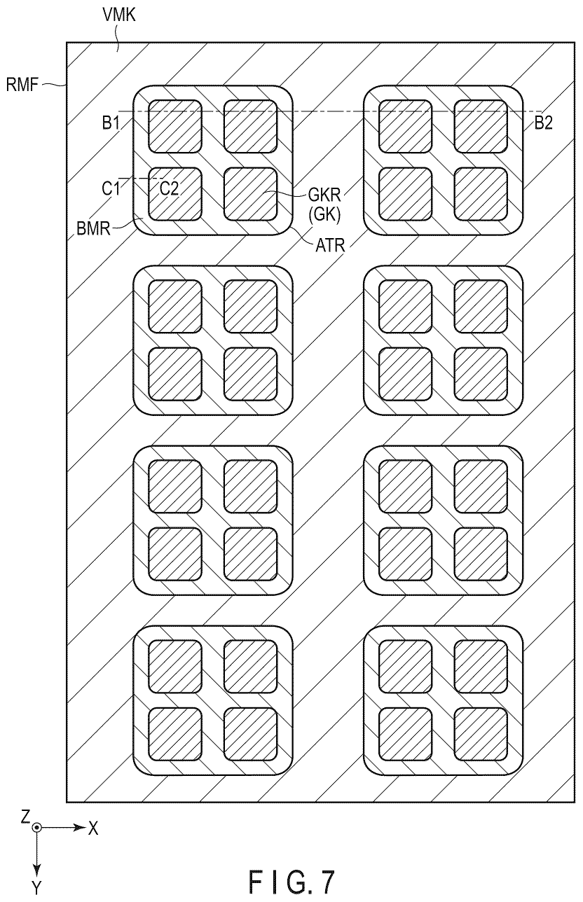

FIG. 7 is a plan view showing a configuration of the vapor deposition mask. A vapor deposition mask VMK comprises a retaining frame RMF, a connection region BMR, and a mask region GK. The connection region BMR and the mask region GK are collectively referred to as a thin-film region ATR. The thin-film region ATR has approximately a rectangular shape.

FIG. 7 shows eight thin-film regions ATR, but the number of thin-film regions ATR is not limited to this. Note that the vapor deposition mask VMK should only be provided with a plurality of thin-film regions ATR.

Further, four mask regions GK are provided for each of the plurality of thin-film regions ATR, but the number of mask regions GK is not limited to this. Note that each of the thin-film regions ATR should only be provided with a plurality of mask regions GK.

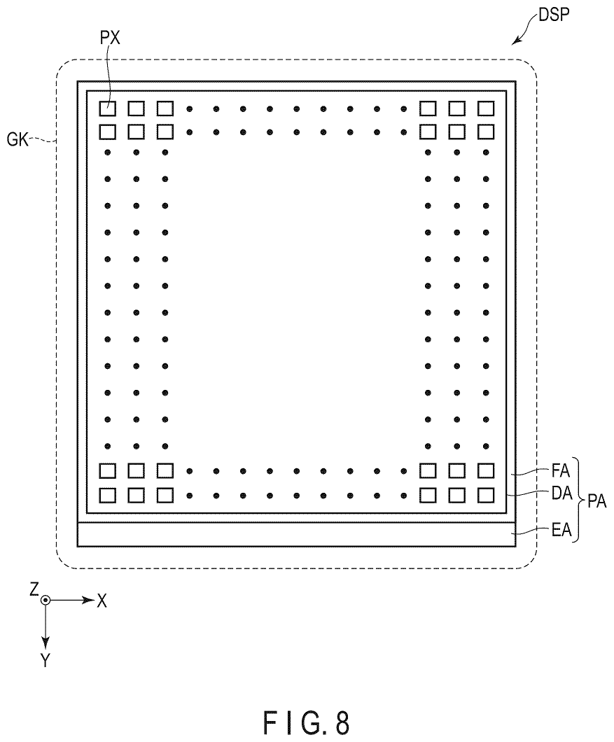

FIG. 8 is a plan view schematically showing an example of the configuration of the display device. FIG. 8 illustrates the relationship between the display area DA and the mask region GK in plan view. As described above, a plurality of pixels PX are provided in the display area DA. The display area DA, the peripheral area FA, and the area EA are collectively referred to as a panel area PA. The mask region GK is provided to cover the panel region PA. In other words, the size of the mask region GK is larger than that of the panel area PA.

Note that in order to make the drawing easier to read, FIG. 8 shows the pixels PX arranged at equal intervals. Note that the arrangement of the pixels PX in this embodiment is as shown in FIG. 2.

Let us now return to FIG. 7. Here, the mask region GK has a rectangular shape in plan view. The rectangular-shaped mask region GK may as be referred to as a mask region GKR.

The connection region BMR is provided between the retaining frame RMF and the mask region GK (rectangular-shaped mask region GKR).

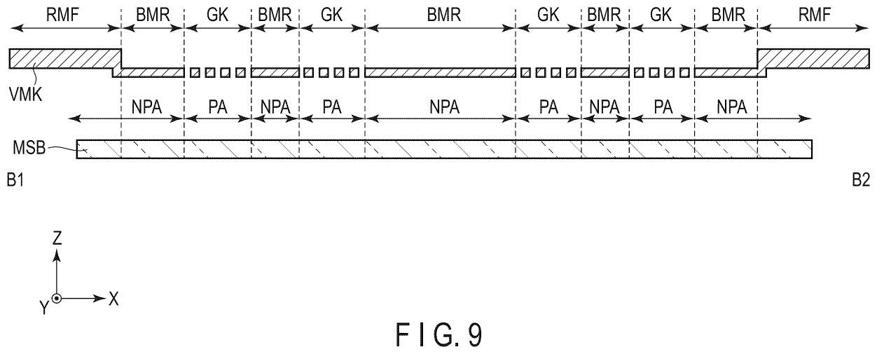

FIG. 9 is a cross-sectional view of the vapor deposition mask and the mother board taken along line B1-B2 shown in FIG. 7. FIG. 9 schematically shows the configurations of the mother board MSB and the vapor deposition mask VMK.

The mother board MSB includes a plurality of backplanes BPS as described above. The position of each of the backplane BPS coincides with the position of the respective panel area PA shown in FIG. 9. The regions of the mother board MSB, where the panel areas PA are not provided, are referred to as areas NPA, respectively.

The vapor deposition mask VMK comprises a retaining frame RMF, connection regions BMR, and mask regions GK, as described above. The mask regions GK are each located to oppose the respective panel region PA. The connection regions BMR area each located to oppose the respective area NPA. As shown in FIG. 8, the mask region GK is larger than the panel region PA. However, in order to make the drawing easier to read, FIG. 9 illustrates the mask regions GK and the panel regions PA appear to have the same size.

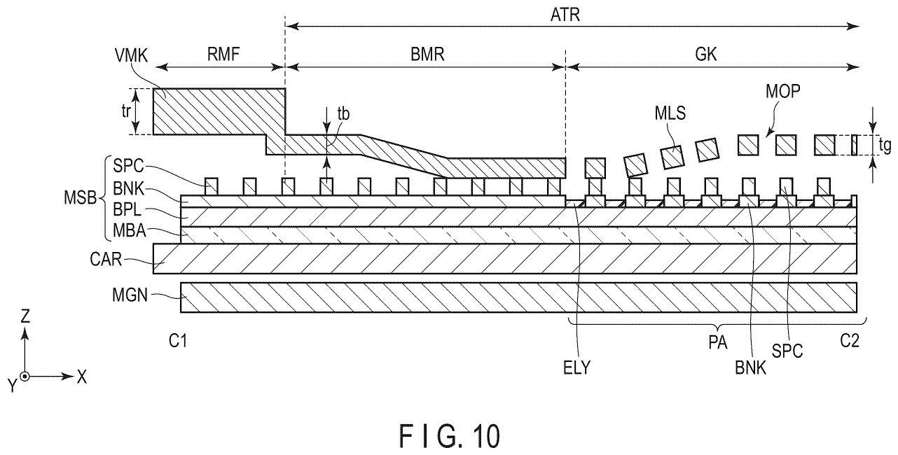

FIG. 10 is a cross-sectional view of the vapor deposition mask and the mother board taken along line C1-C2 shown in FIG. 7. FIG. 10 shows a detailed configuration of the vapor deposition mask VMK and the mother board MSB in the deposition process.

The mother board MSB comprises a mother base MBA, a backplane layer BPL, a bank BK, and spacers SPC. The backplane layer BPL is provided on the mother base MBA. The mother board MSB is provided on a board carrier CAR. The board carrier CAR is disposed on a magnet MGN. The bank BK is provided between each adjacent pair of anodes AD (not shown) in the panel region PA. In the mask region GK, the bank BK may be provided uniformly or, may be provided as islands at regular intervals as in the panel region PA. The spacers SPC are provided on the bank BK.

The vapor deposition mask VMK comprise a retaining frame RMF, connection regions BMR, and mask regions GK, as described above. The mask regions GK each comprises a shielding region MLS and an aperture region MOP. The aperture region MOP is provided to correspond to the respective aperture OP of each individual panel region PA (the display device DSP). Note that no aperture region is provided in the connection regions BMR. The connection regions BMR are all shielding regions.

The retaining frame RMF, the connection regions BMR, and the mask regions GK may be formed of the same material or of different metal materials. Alternatively, the retaining frame RMF may be formed of a first metal material and the connection regions BMR and mask regions GK may be of a second metal material.

The retaining frame RMF is made of an alloy such as Invar, for example. The Invar alloys have low coefficient of thermal expansion at room temperature, and thus have the advantage of not causing stress to the connection regions BMR and mask regions GK in an environment where the temperature changes occur throughout the deposition process.

The length (thickness) of the retaining frame RMF along the third direction Z is referred to as a thickness tr. The length (thickness) of the connection regions BMR along the third direction Z is referred to as a thickness tb. The length (thickness) of the mask regions GK along the third direction Z is referred to as a thickness tg.

The thickness tr of the retaining frame RMF is greater than the thickness tb of the connection regions BMR and the thickness tg of the mask regions GK (tr>tb, tg). The thickness tb of the connection regions BMR and the thickness tg of the mask regions GK should be the same (tb=tg). In other words, the relationship: tr>tb=tg can be established.

The thickness tr of the retaining frame RMF is, for example, 0.5 mm or more and 1.5 mm or less, preferably 0.8 mm or more and 1.2 mm or less. In this embodiment, the thickness tr of the retaining frame RMF is set to 1 mm. Note that the retaining frame RMF may be constituted by a single layer or a stacked multiplayer of thin plates.

The thickness tb of the connection regions BMR and the thickness tg of the mask regions GK, that is, the thickness of the thin-film region ATR is, for example, 3 μm or more and 20 μm or less, preferably 5 μm or more and 10 μm or less. In this embodiment, the thickness tb of the connection regions BMR and the thickness tg of the mask regions GK are set to 5 μm.

The connection regions BMR are solid metal thin film having the above-mentioned thickness. Therefore, the mask regions can be said as a thin metal film having the above-mentioned thickness and a plurality of aperture regions MOP formed therein.

When the organic EL material is deposited, the mask regions GK are placed in close proximity to the mother board MSB by the magnetic force of the magnet MGN. The organic EL material from the deposition source is deposited between each adjacent portions of the bank BK via the aperture regions MOP of the mask regions GK, thereby forming the organic EL layer.

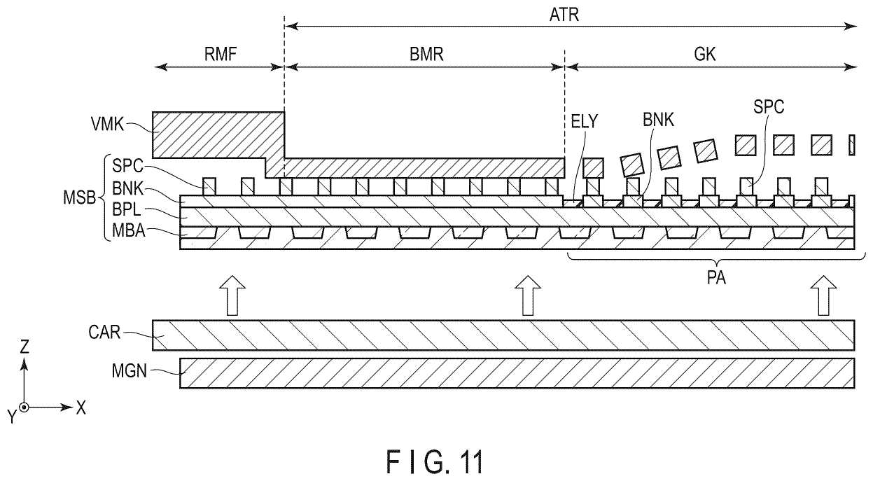

FIG. 11 is a cross-sectional view showing a configuration of the vapor deposition mask and the mother board after completion of the deposition process. After the deposition process is finished, the magnetic force of the magnet MGN is released and the vapor deposition masks VMK are separated from the mother board MSB. However, the mother board MSB charged may stick to the vapor deposition masks VMK. As a result, the mother board MSB may undesirably drop off the board carrier CAR. If such a drop-off occurs, the subsequent processing steps in the manufacture are adversely affected, and the production yield of the display device may undesirably decrease.

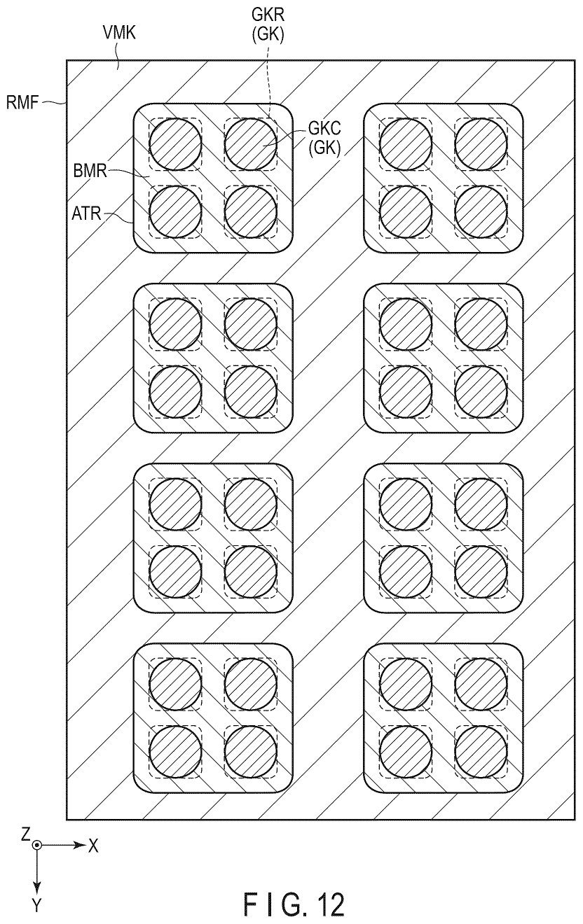

FIG. 12 is a plan view showing a configuration of the vapor deposition mask. In the vapor deposition mask VMK shown in FIG. 12, the mask regions GK have a circular shape in plan view. The circular-shaped mask regions GK are as well referred to as mask regions GKC.

The attachment of the mother board MSB to the vapor deposition masks VMK more likely occur in the case of the vapor deposition mask VMK including the circular-shaped mask regions GKC than in the case of the vapor deposition mask VMK including the rectangular-shaped mask regions GKR.

The circular-shaped mask regions GKC are smaller than rectangular-shaped mask regions GKR. The area of the connection regions BMR in the vapor deposition mask VMK including the circular-shaped mask regions GKC is larger than the area of the connection regions BMR in the vapor deposition mask VMK including the rectangular-shaped mask region GKR. That is, it can be said that as the area of the connection regions BMR becomes larger, the mother board MSB can the easily stick to the vapor deposition mask VMK.

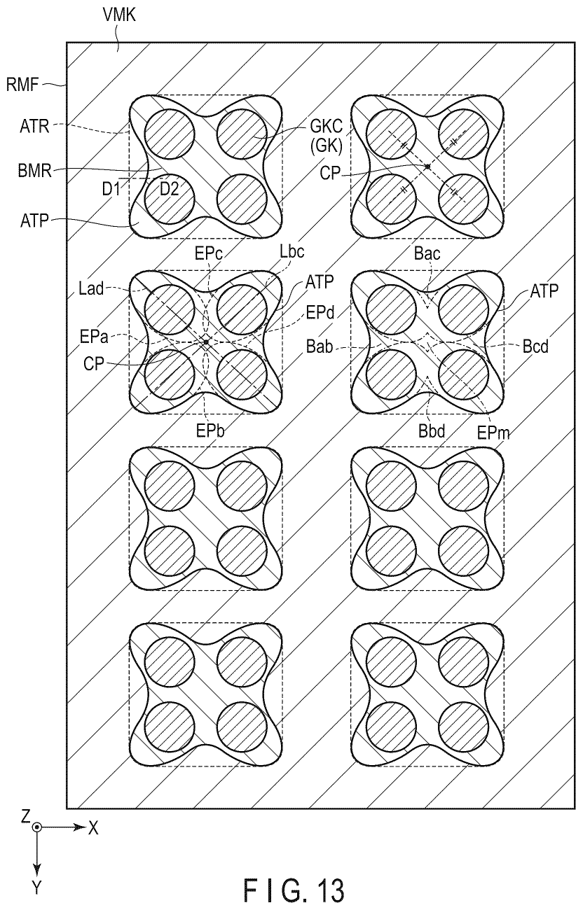

FIG. 13 is a plan view showing a configuration of the vapor deposition mask. The vapor deposition mask VMK shown in FIG. 13 comprises circular-shaped mask regions GKC and propeller-shaped thin film regions ATP. FIG. 13 shows that four mask regions GK are disposed on an inner side of each one connection region BMR.

The thin-film regions ATP each comprise an ellipse-shaped region EPa, region EPb, region EPc, and region EPd, which surround four mask regions GKC, respectively. Here, the point located at equal distances from the four mask regions GKC is referred to as an imaginary point CP. Imaginary lines extending from the major axes of the ellipse-shaped region EPa, region EPb, region EPc, and region EPd each pass through the imaginary point CP. Imaginary lines extending from the major axes of the ellipse-shaped region EPa and region EPd constitute one straight line Lad. Imaginary lines extending from the major axes of the ellipse-shaped region EPb and region EPc constitute one straight line Lbc.

The region EPa and region EPb are located to be line-symmetrical with respect to the first direction X. The region EPc and region EPd are located to be line-symmetrical with respect to the first direction X. The region EPa and region EPc are located to be line-symmetrical with respect to the second direction Y. The region EPb and region EPd are located to be line-symmetrical with respect to the second direction Y.

Here, the region surrounded by the region EPa, region EPb, region EPc, and region EPd is referred a region EPm. Further, the region between the region EPa and region EPb, the region between the region EPa and region EPc, the region between the region EPc and region EPd, and the region between the region EPb and region EPd are referred to as a region Bab, a region Bac, a region Bcd, and a region Bbd, respectively. The region EPm has a rhombic shape with curved edges. The region Bab, region Bac, region Bcd, and region Bbd each have a triangular shape with curved edges.

From the above-provided descriptions, it can be said that the propeller-shaped thin-film region ATP includes a region EPa, a region EPb, a region EPc, a region EPd, a region EPm, a region Bab, a region Bac, a region Bcd, and a region Bbd. One connection region BMR is a region excluding the four mask regions GKC from one thin-film region ATP.

By making the thin-film region ATP into a propeller-shaped, the area of the connection regions BMR can be reduced even if the mask regions GKC are circular-shaped. With this configuration, it is possible to suppress the mother board MSB from attaching to the vapor deposition mask VMK.

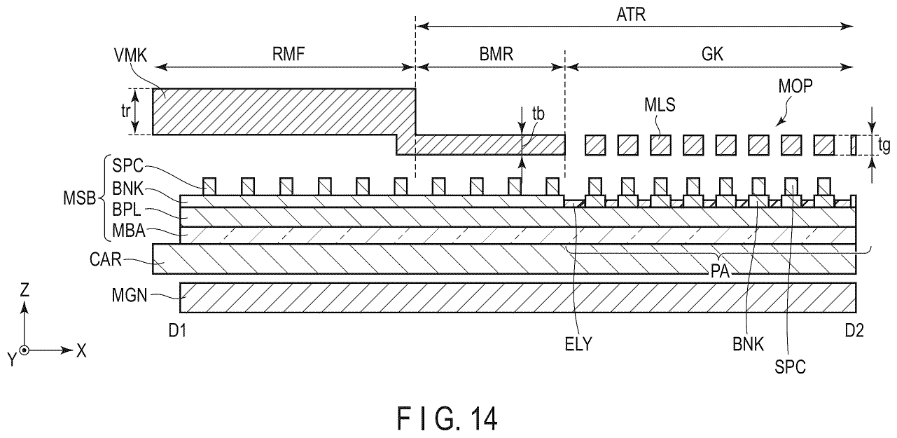

FIG. 14 is a cross-sectional view showing the vapor deposition mask and the mother board taken along line D1-D2 shown in FIG. 13. In the vapor deposition mask VMK shown in FIG. 14, the area of the connection regions BMR is small and therefore the mother board MSB does not attach to the vapor deposition mask VMK.

In the vapor deposition mask VMK shown in FIG. 14, the thickness tr of the retaining frame RMF, the thickness tb of the connection region BMR, and the thickness tg of the mask region GK are similar to those illustrated in FIG. 10.

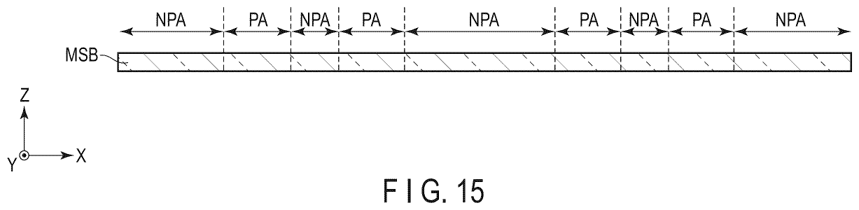

FIGS. 15 to 21 are cross-sectional views illustrating a method of manufacturing a display device using the vapor deposition mask shown in FIG. 13.

First, a mother board MSB including panel regions PA and regions NPA is manufactured (see FIG. 15). As described above, each of the panel regions PA is provided with a backplane BPS. An enlarged view of the mother board MSB shown in FIG. 15 corresponds to FIG. 4.

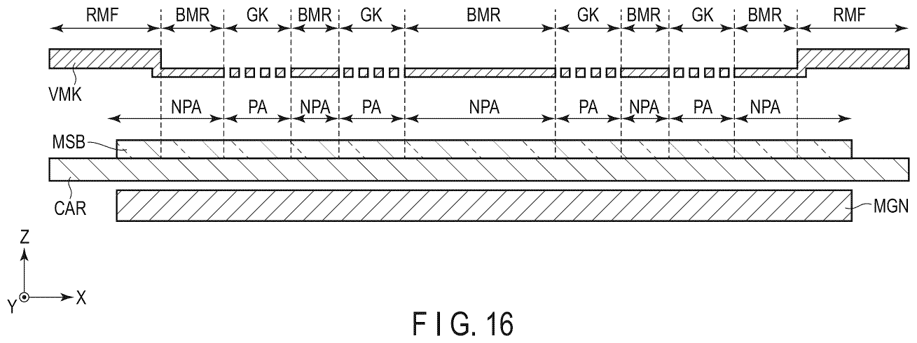

The mother board MSB is placed on a board carrier CAR in a deposition device not shown in the figure. A magnet MGN is installed below the board carrier CAR. The vapor deposition mask VMK is disposed on the mother board MSB (see FIG. 16). That is, the board carrier CAR and the mother board MSB are disposed between the magnet MGN and the vapor deposition mask VMK.

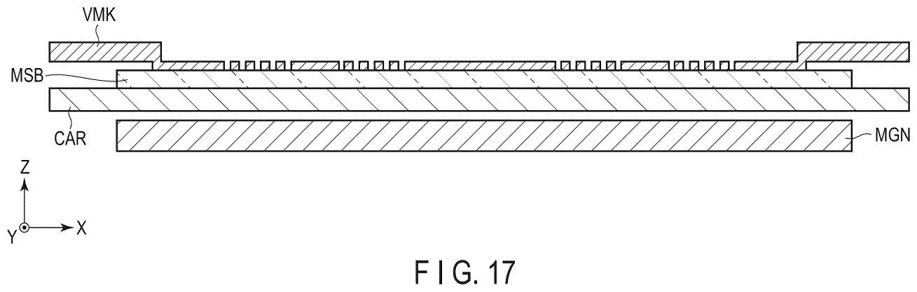

A magnetic force is generated from the magnet MGN. By the magnetic force, the vapor deposition mask VMK is disposed in close proximity to the mother board MSB (see FIG. 17). The deposition source, not shown in the figure, is heated, and organic EL material is deposited from the deposition source onto the mother board MSB. An enlarged view of the mother board MSB on which the organic EL material is deposited corresponds to FIG. 5.

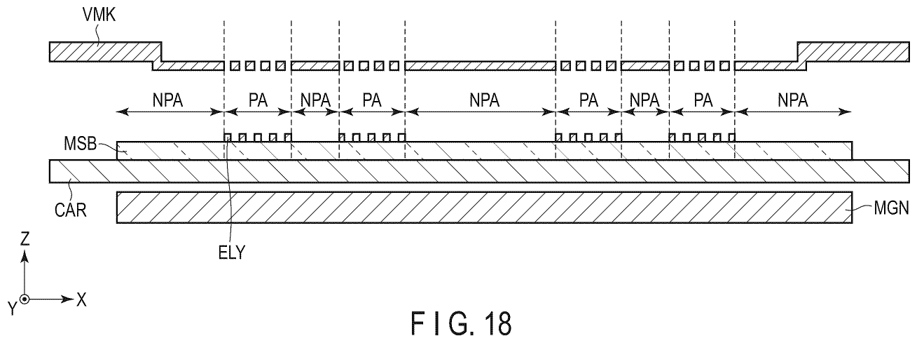

Then, the magnetic force of the magnet MGN is released and the vapor deposition mask VMK is separated from the mother board MSB (see FIG. 18). As shown in FIG. 18, the organic EL layer is formed on the mother board MSB. Here, since the connection region BMR is small, the vapor deposition mask VMK does not attach to the mother board MSB.

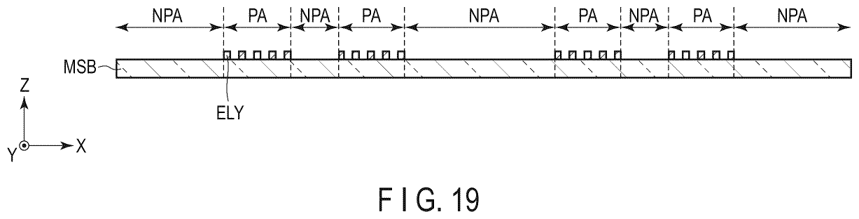

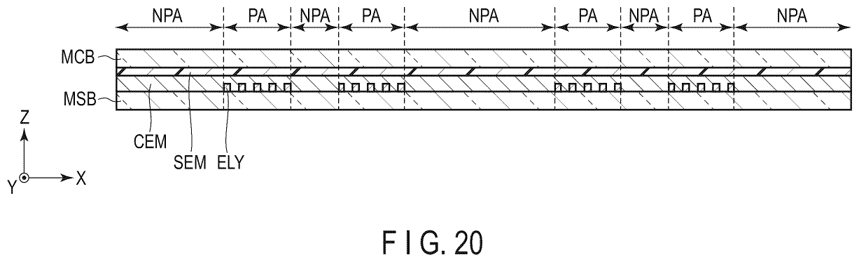

The mother board MSB on which the organic EL layer ELY is formed is removed from the deposition device (see FIG. 19). On the organic EL layer ELY, a common electrode CEM, an insulating layer SEM, and a base MCB are provided (see FIG. 20). The common electrode CEM, the insulating layer SEM, and the base MCB are from the same materials as those of the common electrode CE, the insulating layer SEY, and the base BA2, respectively.

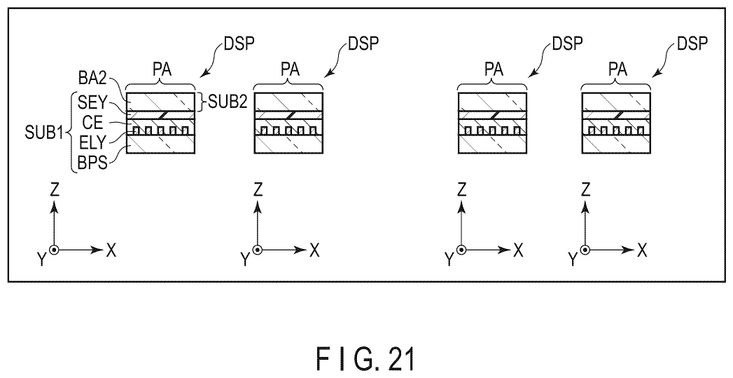

The stacked body of the mother board MSB, the organic EL layer ELY, the common electrode CEM, the insulating layer SEM, and the base MCB is divided into pieces for each panel area PA. With this operation, display devices DSP each including a backplane BPS, an organic EL layer ELY, a common electrode CE, an insulating layer SEY, and a base BA2 can be individually obtained (see FIG. 21).

The vapor deposition mask VMK of this embodiment includes propeller-shaped thin-film regions ATP. Each of the thin-film region ATP is provided with a plurality of circular-shaped mask regions GKC. Each of the circular-shaped mask regions GKC is provided with a plurality of aperture regions MOP.

In the deposition process, the organic EL material from the deposition source is deposited into each of the apertures OP of the pixels PX in the display area DA via the aperture regions MOP. With this operation, the organic EL layer ELY of the display device DSP can be formed.

With the vapor deposition mask VMK of this embodiment, the area of the connection regions BMR can be reduced. Therefore, it is possible to suppress the mother board MSB from attaching to the vapor deposition mask VMK even after the deposition process. The mother board MSB can be prevented from dropping off the board carrier. By preventing the mother board MSB from dropping off, the production yield of display devices can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a display device, comprising:
disposing a substrate including a plurality of panel regions on a board carrier;
disposing a vapor deposition mask to oppose the substrate;
disposing a magnet to oppose the vapor deposition mask while interposing the substrate therebetween;
bringing the vapor deposition mask into close proximity to the substrate by a magnetic force of the magnet; and
depositing an organic EL material from an evaporation source onto the substrate via the vapor deposition mask by heating the evaporation source, thereby forming an organic EL layer, wherein
the vapor deposition mask comprises a plurality of thin-film regions and a retaining frame,
each of the plurality of thin-film regions includes a plurality of mask regions and connection regions,
each of the plurality of thin-film regions has a propeller shape,
each of the plurality of mask regions has a circular shape, and
each of the plurality of mask regions comprises a plurality of aperture regions.

2. The method according to claim 1, wherein
four of the mask regions are provided in each one the thin-film regions, and
each of the thin-film regions comprises four first regions which are ellipse-shape and surround the four mask regions, a second region surrounded by the four first regions, and a third region provided between each respective adjacent pair of the first regions.

3. The method according to claim 2, wherein
the second region has a rhombic shape with curved edges, and
the third region has a triangular shape with curved edges.

4. The method according to claim 2, wherein
when a point equally distant from the four mask regions is defined as an imaginary point, an imaginary line extending from a major axis of each of the four first regions passes through the imaginary point.

5. A vapor deposition mask comprising:
a plurality of thin-film regions and a retaining frame, wherein
each of the plurality of thin-film regions includes a plurality of mask regions and connection regions,
each of the plurality of thin-film regions has a propeller shape,
each of the plurality of mask regions has a circular shape,
each of the plurality of mask regions comprises a plurality of aperture regions,
four of the mask regions are provided in each one the thin-film regions,
each of the thin-film regions comprises four first regions which are ellipse-shaped and surround the four mask regions, a second region surrounded by the four first regions, and a third region provided between each adjacent pair of the first regions.

6. The vapor deposition mask according to claim 5, wherein
the second region has a rhombic shape with curved edges, and
the third region has a triangular shape with curved edges.

7. The vapor deposition mask according to claim 5, wherein
when a point equally distant from the four mask regions is defined as an imaginary point, an imaginary line extending from a major axis of each of the four first regions passes through the imaginary point.

8. The vapor deposition mask according to claim 5, wherein
a thickness of the retaining frame is greater than a thickness of the thin-film regions.

9. The vapor deposition mask according to claim 8, wherein
the thickness of the retaining frame is 0.5 mm or more and 1.5 mm or less, and
the thickness of the thin-film regions is 3 μm or more and 20 μm or less.
